(19) United States
(12) Patent Application Publication
(10) Pub. No.: US 2004/0245624 A1
(43) Pub. Date: Dec. 9, 2004

(54) Using solder balls of multiple sizes to couple one or more semiconductor structures to an electrical device

(76) Inventors: Leland S. Swanson, McKinney, TX (US); Gregory E. Howard, Dallas, TX (US)

Correspondence Address: TEXAS INSTRUMENTS INCORPORATED, P O BOX 655474, M/S 3999, DALLAS, TX, 75265

(21) Appl. No.: 10/453,445

(22) Filed: Jun. 3, 2003

(51) Int. Cl. H01L 23/12

(52) U.S. Cl. 257/711

(57) ABSTRACT

In one embodiment, solder balls of multiple sizes may be used to couple one or more semiconductor structures to an electrical device. For example, a printed circuit board structure may support one or more integrated circuit packages includes at least one package with a substrate having a bottom surface. The structure may also include a printed circuit board that includes: (1) one or more first regions each having a top surface opposite the bottom surface of the substrate and separated from the bottom surface by a first distance; and (2) one or more second regions each having a top surface opposite the bottom surface of the substrate and separated from the bottom surface of the substrate by a second distance, the top surface of the second region being closer to the bottom surface of the substrate than the top surface of the first region such that the second distance is smaller than the first distance. One or more first solder ball may be used to couple the substrate to the board at the first regions, and one or more second solder balls that are smaller than the one or more first balls may be used to couple the substrate to the board at the second regions, the first and second balls providing electrical connectivity between circuitry associated with the package and circuitry associated with the board.

### TECHNICAL FIELD OF THE INVENTION

This invention relates generally to electrical device structures and more particularly to using solder balls of multiple sizes to couple one or more semiconductor structures to an electrical device.

### BACKGROUND

A printed circuit board structure may include one or more integrated circuit packages coupled to a printed circuit board. Solder balls may be used to provide electrical connectivity between circuitry associated with the integrated circuit package and circuitry associated with the printed circuit board. Certain integrated circuit packages may include or even require small solder ball pitches (i.e. center-to-center separation between solder balls) and thus small solder balls, for example, to provide desired electrical connectivity between the circuitry associated with the integrated circuit package and the circuitry associated with the printed circuit board. However, as the size of the solder balls decreases, the physical connections between the solder balls and the integrated circuit package and between the solder balls and the printed circuit board may be weaker, such that the reliability of the structure or a device associated with the structure may also decrease.

### SUMMARY OF THE INVENTION

According to the present invention, certain disadvantages and problems associated with previous printed circuit board structures supporting one or more integrated circuit packages using solder balls may be reduced or eliminated.

In one embodiment, solder balls of multiple sizes may be used to couple one or more semiconductor structures to an electrical device. For example, a printed circuit board structure may support one or more integrated circuit packages includes at least one printed circuit board having a top surface. The structure may also include at least one package comprising a substrate that includes: (1) one or more first regions each having a bottom surface opposite the top surface of the board and separated from the top surface of the board by a first distance; and (2) one or more second regions each having a bottom surface opposite the top surface of the board and separated from the top surface of the board by a second distance, the bottom surface of the second region being closer to the surface of the board than the bottom surface of the first region such that the second distance is smaller than the first distance. One or more first solder balls may be used to couple the board to the substrate at the first regions, and one or more second solder balls that are smaller than the one or more first balls may be used to couple the board to the substrate at the second regions, the first and second balls providing electrical connectivity between circuitry associated with the board and circuitry associated with the package.

Particular embodiments of the present invention may provide one or more technical advantages. For example, in certain embodiments, solder balls of multiple sizes may be used to couple a substrate associated with an integrated circuit package to a printed circuit board. The larger solder balls may provide stronger physical connections to the substrate and printed circuit board to provide better mechanical stability for the printed circuit board structure, which may improve reliability. These larger solder balls may be used, for example, for power and ground connections. The smaller solder balls may provide a higher number of electrical connections between circuitry associated with the integrated circuit package and circuitry associated with the printed circuit board, which may enable a high density interconnect between the integrated circuit package and the printed circuit board. In certain embodiments, the solder ball pitch (i.e. center-to-center separation between certain solder balls) may be less than 0.5 mm.

Certain embodiments of the present invention may provide some, all, or none of the above technical advantages. Certain embodiments may provide one or more other technical advantages, one or more of which may be readily apparent to those skilled in the art from the figures, descriptions, and claims included herein.

### BRIEF DESCRIPTION OF THE DRAWINGS

For a more complete understanding of the present invention and features and advantages thereof, reference is now made to the following description, taken in conjunction with the accompanying drawings, in which:

FIG. 1 illustrates an example printed circuit board structure supporting one or more integrated circuit packages using solder balls of multiple sizes, in which larger first solder balls couple a printed circuit board to one or more first regions of a substrate and smaller second solder balls couple the printed circuit board to one or more built-up regions formed at one or more second regions of the substrate;

FIG. 2 illustrates an example printed circuit board structure supporting one or more integrated circuit packages using solder balls of multiple sizes, in which larger first solder balls couple a printed circuit board to one or more recessed regions formed at one or more first regions of a substrate and smaller second solder balls couple the printed circuit board to one or more second regions of the substrate;

FIG. 3 illustrates an example printed circuit board structure supporting one or more integrated circuit packages using solder balls of multiple sizes, in which larger first solder balls each couple a printed circuit board to a corresponding recessed region at a corresponding first region of a substrate and smaller second solder balls couple the printed circuit board to one or more second regions of the substrate;

FIG. 4 illustrates an example method for providing a printed circuit board structure supporting one or more integrated circuit packages using solder balls of multiple sizes;

FIG. 5 illustrates an example printed circuit board structure supporting one or more integrated circuit packages using solder balls of multiple sizes, in which larger first solder balls couple a substrate to one or more first regions of a printed circuit board and smaller second solder balls couple the substrate to one or more built-up regions formed at one or more second regions of the printed circuit board;

FIG. 6 illustrates an example printed circuit board structure supporting one or more integrated circuit packages using solder balls of multiple sizes, in which larger first solder balls couple a substrate to one or more recessed regions formed at one or more first regions of a printed circuit board and smaller second solder balls couple the substrate to one or more second regions of the printed circuit board;

FIG. 7 illustrates an example printed circuit board structure supporting one or more integrated circuit packages using solder balls of multiple sizes, in which larger first solder balls each couple a substrate to a corresponding recessed region at a corresponding first region of a printed circuit board and smaller second solder balls couple the substrate to one or more second regions of the printed circuit board; and

FIG. 8 illustrates an example method for providing a printed circuit board structure supporting one or more integrated circuit packages using solder balls of multiple sizes.

### DESCRIPTION OF EXAMPLE EMBODIMENTS

The present invention includes using solder balls of multiple sizes to couple a surface of each of one or more semiconductor structures to a surface of an electrical device to provide electrical connectivity between circuitry associated with the one or more semiconductor structures and circuitry associated with the electrical device. A semiconductor structure may include a semiconductor device, an integrated circuit, an integrated circuit package, or any other suitable semiconductor structure according to particular needs. An electrical device may include a semiconductor device, an integrated circuit, an integrated circuit package, a printed circuit board, an electrical component, an electronics device, or any other suitable electrical device according to particular needs. For example, an electrical device may include an electronics device that may interface with an integrated circuit package. An electronics device may include a device such as a switch, a radio, a speaker, or any other suitable electronics device. Although the particular example of using solder balls of multiple sizes to couple a bottom surface of at least one integrated circuit package substrate to the top surface of a printed circuit board is primarily described, the present invention contemplates using solder balls of multiple sizes to couple a top or bottom surface of any suitable semiconductor structure to a bottom or top surface, respectively, of any suitable electrical device.

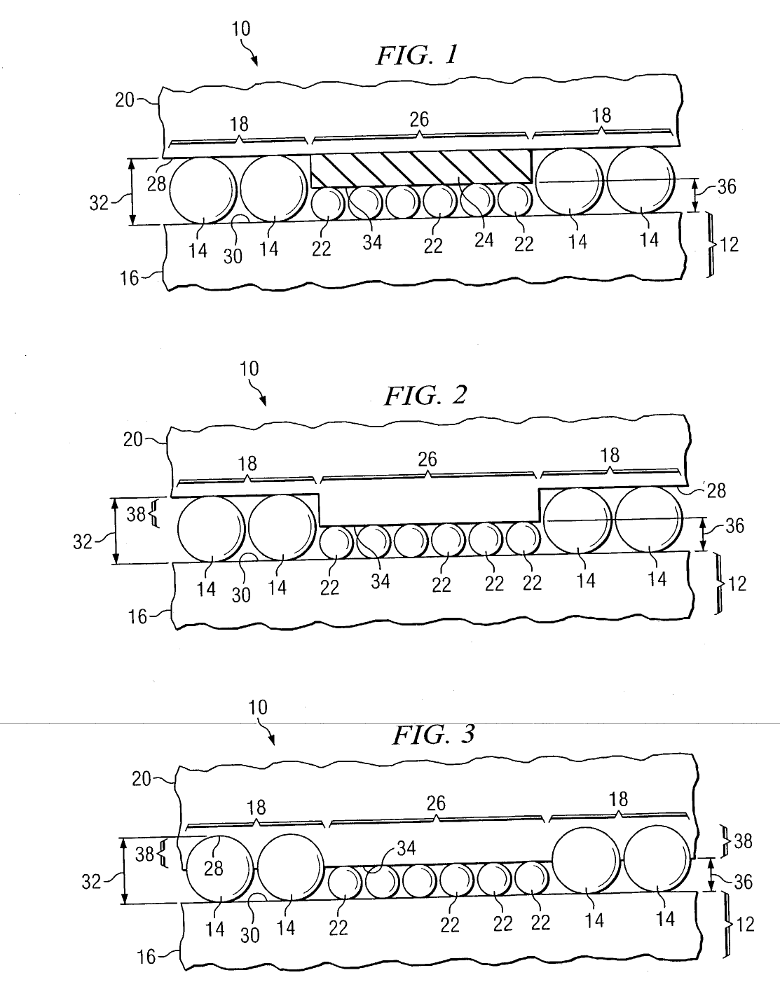

FIG. 1 illustrates an example printed circuit board structure 10 supporting one or more integrated circuit packages 12 using solder balls of multiple sizes, in which larger first solder balls 14 couple a printed circuit board 16 to one or more first regions 18 of a substrate 20 and smaller second solder balls 22 couple printed circuit board 16 to one or more built-up regions 24 formed at one or more second regions 26 of substrate 20. Structure 10 includes at least one printed circuit board 16 that includes circuitry surrounded by, for example, a dielectric or other suitable material.

Although structure 10 may include any suitable number and types of integrated circuit packages 12, this description focuses for simplicity on a single integrated circuit package 12 with a substrate 20. Substrate 20 includes circuitry associated with its corresponding integrated circuit package 12 and surrounded by, for example, a dielectric or other suitable material. In certain embodiments, substrate 20 may include a standard laminate. Substrate 20 includes one or more first regions 18 each having a bottom surface 28 opposite a top surface 30 of printed circuit board 16 and separated from top surface 30 of printed circuit board 16 by a first distance 32. Substrate 20 also includes one or more second regions 26 each having a bottom surface 34 opposite top surface 30 of printed circuit board 16 and separated from top surface 30 of printed circuit board 16 by a second distance 36. Bottom surface 34 of second region 26 is closer to top surface 30 of printed circuit board 16 than bottom surface 28 of first region 18 such that second distance 36 is smaller than first distance 32. First distance 32 and second distance 36 may each be any suitable distance, and first region 18 and second region 26 may have any suitable areas, according to particular needs. Additionally, in an embodiment in which structure 10 includes multiple first regions 18, each first distance 32 may be any suitable distance and each first region 18 may have any suitable area relative to other first regions 18, according to particular needs. In an embodiment in which structure 10 includes multiple second regions 26, each second distance 36 may be any suitable distance and each second region 26 may have any suitable area relative to other second regions 26, according to particular needs.

Structure 10 includes one or more first solder balls 14 coupling printed circuit board 16 to substrate 20 at the one or more first regions 18 of substrate 20 to provide electrical connectivity between circuitry associated with printed circuit board 16 and circuitry associated with integrated circuit package 12. For example, first solder balls 14 may contact metal or other conductive material at both printed circuit board 16 and substrate 20 such that first solder balls 14 may provide electrical conductivity between circuitry associated with printed circuit board 16 and integrated circuit package 12. For example, first solder balls 14 may be used for power and ground connections. In certain embodiments, first solder balls 14 may include tin-lead, high lead, or may be lead free; however, the present invention contemplates first solder balls 14 including any suitable material according to particular needs. First solder balls 14 may have any suitable shape and material density. Although first solder balls 14 are illustrated as being the same size, first solder balls 14 may vary in size if appropriate. Additionally, although a specific number of first solder balls 14 are illustrated, structure 10 may include any suitable number of first solder balls 14 according to particular needs. First solder balls 14 may have any suitable pitch (i.e. center-to-center separation between first solder balls 14). Because of their larger size, first solder balls 14 may provide stronger physical connections to printed circuit board 16 and substrate 20 to provide better mechanical stability for printed circuit board structure 10, which may improve reliability.

Structure 10 also includes one or more second solder balls 22 coupling printed circuit board 16 to substrate 20 at the one or more second regions 26 of substrate 20 to provide electrical connectivity between the circuitry associated with printed circuit board 16 and the circuitry associated with integrated circuit package 12. For example, second solder balls 22 may contact metal or other conductive material at both printed circuit board 16 and substrate 20 such that second solder balls 22 may provide electrical conductivity between circuitry associated with printed circuit board 16 and integrated circuit package 12. In certain embodiments, second solder balls 22 may include tin-lead, high lead, or may be lead free; however, the present invention contemplates second solder balls 22 including any suitable material according to particular needs. In one embodiment, second solder balls 22 include a different material than first solder balls 14. According to the present invention, second solder balls 22 are smaller than first solder balls 14, such that second distance 36 is smaller than first distance 32. Second solder balls 22 may have any suitable shape and material density. In one embodiment, it may be preferable for second solder balls 22 to be high density. Although second solder balls 22 are illustrated as being the same size, second solder balls 22 may vary in size if appropriate. Additionally, although a specific number of second solder balls 22 are illustrated, structure 10 may include any suitable number of second solder balls 22 according to particular needs. Second solder balls 22 may have any suitable pitch (i.e. center-to-center separation between second solder balls 22). For example, in certain embodiments, it may be possible to achieve pitches of less than 0.5 mm.

Although structure 10 is shown as including one row including first solder balls 14 and second solder balls 22, structure 10 may include first solder balls 14 and second solder balls 22 in any suitable arrangement within one or more first regions 18 and one or more second regions 26, respectively.

In one embodiment, each second region 26 of substrate 20 includes a built-up region 24 (as illustrated in FIG. 1, for example) formed on the bottom of a standard substrate, second solder balls 22 coupling printed circuit board 16 to substrate 20 at each built-up region 24. Built-up region 24 may be formed in any suitable manner. In one embodiment, built-up region 24 may be an extension of substrate 20. For example, substrate 20 may be formed by depositing one or more laminate layers. These laminate layers may be pre-cut or stamped in such a way that built-up region 24 is formed as substrate 20 is constructed. As another example, built-up region 24 may be formed using patterning and deposition techniques. As another example, built-up region 24 may include multiple metal layers. In one embodiment, built-up region 24 may include a dielectric material substantially the same as a dielectric material of printed circuit board 20; however, the present invention contemplates built-up region 24 including any suitable material. Built-up region 24 may have any suitable height, according to particular needs with respect to the sizes of first solder balls 14 and second solder balls 16. The height of built-up region 24 should ensure that, in a particular structure 10, first solder balls 14 make contact with both printed circuit board 16 and substrate 20, and second solder balls 22 make contact with both printed circuit board 16 and built-up region 24.

In addition to certain features described above with reference to FIG. 1, FIG. 2 illustrates an example printed circuit board structure 10 supporting one or more integrated circuit packages 12 using solder balls of multiple sizes, in which larger first solder balls 14 couple printed circuit board 16 to one or more recessed regions 38 formed at one or more first regions 18 of substrate 20 and smaller second solder balls 22 couple printed circuit board 16 to one or more second regions 26 of substrate 20. In the printed circuit board structure 10 illustrated in FIG. 2, first regions 18 of substrate 20 each include a recessed region 38, each first solder ball 14 coupling printed circuit board 16 to substrate 20 at the recessed region 38 of the first region 18 corresponding to the first solder ball 14.

Recessed regions 38 may have any suitable depths (upward and into substrate 20), according to particular needs. The depth of recessed regions 38 should ensure that, in a particular structure 10, first solder balls 14 make contact with both printed circuit board 16 and substrate 20, and second solder balls 22 make contact with both printed circuit board 16 and substrate 20. In one embodiment, bottom surface 28 of first region 18 may include the bottom of recessed regions 38 such that the first distance 32 of a first region 18 is the separation between the bottom of recessed region 38 and top surface 30 of printed circuit board 16. Recessed regions 38 may include a metal contact or other suitable conductive material such that first solder balls 14 may provide electrical connectivity between circuitry associated with printed circuit board 16 and integrated circuit package 12.

Recessed regions 38 may be formed in any suitable manner, according to particular needs. For example, substrate 20 may be formed by depositing one or more laminate layers. These laminate layers may be pre-cut or stamped in such a way that recessed regions 38 are formed as substrate 20 is constructed. As another example, recessed regions 38 may be formed using any suitable patterning and etching techniques.

In addition to certain structures described above with reference to FIGS. 1 and 2, FIG. 3 illustrates an example printed circuit board structure 10 supporting one or more integrated circuit packages 12 using solder balls of multiple sizes, in which larger first solder balls 14 each couple printed circuit board 16 to a corresponding recessed region 38 at a corresponding first region 18 of a substrate 20 and smaller second solder balls 22 couple printed circuit board 16 to one or more second regions 26 of substrate 20. In the printed circuit board structure 10 illustrated in FIG. 3, each first solder ball 14 couples printed circuit board 16 to substrate 20 at a corresponding one of the recessed regions 38 and substantially fills the corresponding one of the recessed regions 38. For example, each first solder ball 14 may be embedded in its corresponding recessed region 38. In one embodiment, recessed regions 38 may each include a via extending into substrate 20. In this embodiment, each first solder ball 14 substantially fills the via of its corresponding recessed region 38. Each recessed region 38 may form a substantially hemispherical-shaped hole in substrate 20. Each first region 18 may include any suitable number of recessed regions 38 in which a first solder ball 14 is embedded.

Recessed regions 38 may have any suitable depths, according to particular needs. The depth of recessed regions 38 should ensure that, in a particular structure 10, first solder balls 14 make contact with both printed circuit board 16 and substrate 20, and second solder balls 22 make contact with both printed circuit board 16 and substrate 20. In one embodiment, bottom surface 28 of first region 18 may include the bottom of recessed regions 38 such that the first distance 32 of a first region 18 is the separation of the bottom of recessed region 38 and top surface 30 of printed circuit board 16. Recessed regions 38 may include a metal contact or other suitable conductive material such that first solder balls 14 may provide electrical connectivity between circuitry associated with printed circuit board 16 and integrated circuit package 12.

Recessed regions 38 may be formed in any suitable manner, according to particular needs. For example, substrate 20 may be formed by depositing one or more laminate layers. These laminate layers may be pre-cut or stamped in such a way that recessed regions 38 are formed as substrate 20 is constructed. As another example, recessed regions 38 may be formed using any suitable patterning and etching techniques such as an isotropic etching technique. As another example, recessed regions 38 may be formed using a drilling technique for drilling into substrate 20. This may include, for example, drilling one or more laminate layers that make up some portion of substrate 20 before using the laminate layers to form substrate 20.

Particular embodiments of the present invention may provide one or more technical advantages. For example, in certain embodiments, solder balls of multiple sizes may be used to couple substrate 20 associated with integrated circuit package 12 to printed circuit board 16. The larger solder balls may provide stronger physical connections to substrate 20 and printed circuit board 16 to provide better mechanical stability for printed circuit board structure 10, which may improve reliability. These larger solder balls may be used, for example, for power and ground connections. The smaller solder balls may provide a higher number of electrical connections between circuitry associated with integrated circuit package 12 and circuitry associated with printed circuit board 16, which may enable a high density interconnect between integrated circuit package 12 and printed circuit board 16. In certain embodiments, the solder ball pitch (i.e. center-to-center separation between certain solder balls) may be less than 0.5 mm.

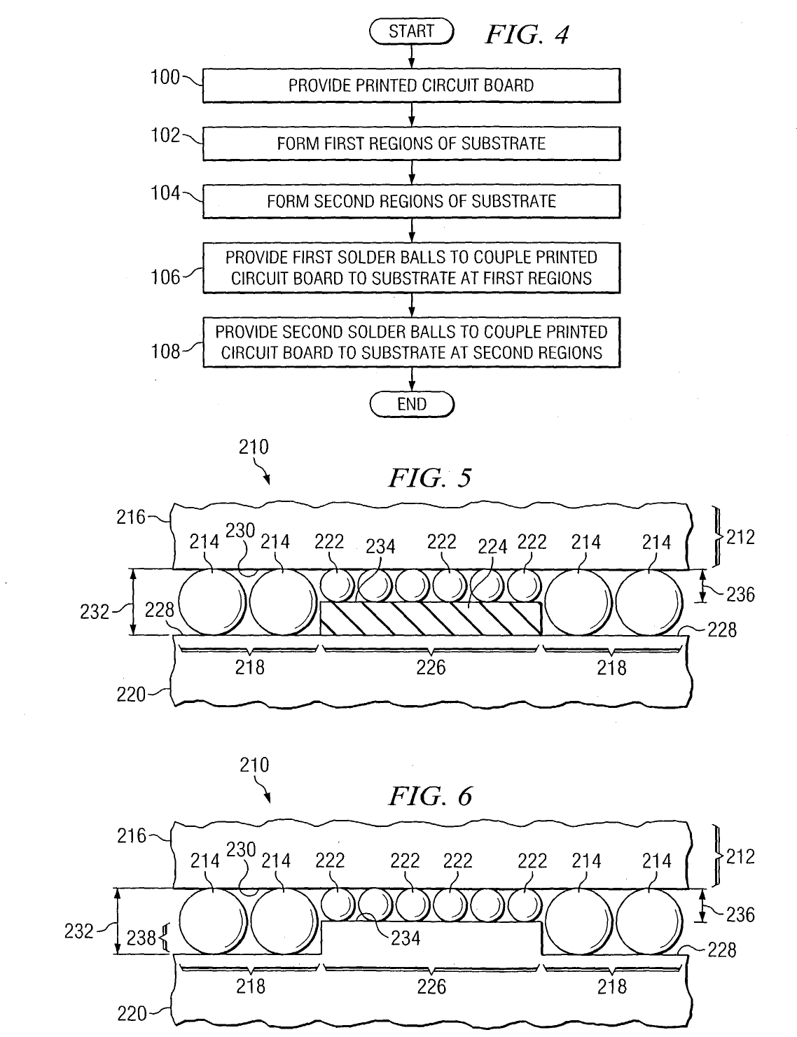

FIG. 4 illustrates an example method for providing a printed circuit board structure 10 supporting one or more integrated circuit packages 12 using solder balls of multiple sizes. At step 100, at least one printed circuit board 16 is provided. Printed circuit board 16 may include or may be coupled to circuitry.

At steps 102 and 104, first regions 18 and second regions 26 of a substrate 20 associated with an integrated circuit package 12 are formed or otherwise provided. At step 102, one or more first regions 18 of printed circuit board 20 are formed or otherwise provided, each having bottom surface 28 opposite a top surface 30 of printed circuit board 16 and separated from top surface 30 of printed circuit board 16 by a first distance 32. At step 104, one or more second regions 26 of substrate 20 are provided, each having bottom surface 34 opposite top surface 30 of printed circuit board 16 and separated from top surface 30 of printed circuit board 16 by second distance 34, bottom surface 34 being closer to top surface 30 of printed circuit board 16 than bottom surface 28 such that second distance 36 is smaller than first distance 32. Steps 102 and 104 may be performed at substantially the same time or in any order according to manufacturing considerations or other particular needs.

In the embodiment illustrated in FIG. 1, step 104 may include providing one or more built-up regions 24 at one or more second regions 26 of substrate 20 on the bottom of a standard substrate 20. In an embodiment in which one or more built-up regions 24 are provided in each second region 26 of substrate 20, each built-up region 24 may include a dielectric material substantially similar to a dielectric material of substrate 20, although built-up region 24 may include any suitable material according to particular needs. Built-up region 24 may be formed in any suitable manner. In one embodiment, built-up region 24 may be an extension of substrate 20. For example, substrate 20 may be formed by depositing one or more laminate layers. These laminate layers may be pre-cut or stamped in such a way that built-up region 24 is formed as substrate 20 is constructed.

In the embodiment illustrated in FIG. 2, step 102 may include forming or otherwise providing one or more recessed regions 38 at one or more first regions 18 of substrate 20 for receiving one or more first solder balls 14 to couple printed circuit board 16 to the one or more recessed regions 38 (bottom referring generally to the deepest point of a recessed region 38). A bottom surface 28 of first regions 18 may include the bottom of recessed regions 38, bottom surface 28 being separated from top surface 30 of printed circuit board 16 by a first distance 32. Recessed regions 38 may be formed in any suitable manner, according to particular needs. For example, substrate 20 may be formed by depositing one or more laminate layers. These laminate layers may be pre-cut or stamped in such a way that recessed regions 38 are formed as substrate 20 is constructed. As another example, recessed regions 38 may be formed using any suitable patterning and etching techniques. In this embodiment, step 104 may include forming or otherwise providing one or more second regions 26 of substrate 20, each having bottom surface 34 opposite top surface 30 of printed circuit board 16 and separated from top surface 30 of printed circuit board 16 by second distance 36, bottom surface 34 being lower relative to bottom surface 28 such that second distance 36 is smaller than first distance 32.

In the embodiment illustrated in FIG. 3, step 102 may include forming or otherwise providing one or more recessed regions 38 at each of one or more first regions 18 of substrate 20, each for receiving a first solder ball 14 to couple printed circuit board 16 to a corresponding one of the recessed regions 38 at a corresponding one of the first regions 18 of substrate 20 and to substantially fill the corresponding one of the recessed regions 38. A bottom surface 28 of first regions 18 may include the bottom of recessed regions 38, bottom surface 28 being separated from top surface 30 of substrate 20 by a first distance 32. In one embodiment, recessed regions 38 may each include a via extending into substrate 20. Recessed regions 38 may be formed in any suitable manner, according to particular needs. For example, substrate 20 may be formed by depositing one or more laminate layers. These laminate layers may be pre-cut or stamped in such a way that recessed regions 38 are formed as substrate 20 is constructed. As another example, recessed regions 38 may be formed using any suitable patterning and etching techniques such as an isotropic etching technique. As another example, recessed regions 38 may be formed using a drilling technique for drilling into substrate 20. This may include, for example, drilling one or more laminate layers that make up some portion of substrate 20 before laying the laminate layers onto substrate 20. In this embodiment, step 104 may include forming or otherwise providing one or more second regions 26 of substrate 20, each having bottom surface 34 opposite top surface 30 of printed circuit board 16 and separated from top surface 30 of printed circuit board 16 by second distance 36, bottom surface 34 being lower relative to bottom surface 28 such that second distance 36 is smaller than first distance 32.

At steps 106 and 108, which are preferably performed at substantially the same time, one or more first solder balls 14 and one or more second solder balls 22 are used to couple printed circuit board 16 to substrate 20. In one embodiment, as illustrated above with reference to FIG. 1, step 106 may include coupling one or more larger first solder balls 14 to printed circuit board 16 and substrate 20 at one or more first regions 18 of substrate 20. In this embodiment, step 108 may include coupling one or more smaller second solder balls 22 to printed circuit board 16 and one or more built-up regions 24 formed at the one or more second regions 26 of substrate 20. In another embodiment, as illustrated with reference to FIG. 2, step 106 may include coupling one or more larger first solder balls 14 to printed circuit board 16 and one or more recessed regions 38 formed at one or more first regions 18 of substrate 20. In this embodiment, step 108 may include coupling one or more smaller second solder balls 22 to printed circuit board 16 and to one or more second regions 26 of substrate 20. In yet another embodiment, as illustrated with reference to FIG. 3, step 106 may include coupling each of one or more larger first solder balls 14 to printed circuit board 16 and a corresponding recessed region 38 at a corresponding first region 18 of substrate 20, each first solder ball 14 substantially filling its corresponding recessed region 38. In this embodiment, step 108 may include coupling one or more smaller second solder balls 22 to printed circuit board 16 and one or more second regions 26 of substrate 20.

The one or more first solder balls 14 and the one or more second solder balls 22 may provide electrical connectivity between circuitry associated with printed circuit board 16 and circuitry associated with integrated circuit package 12. In one embodiment, first solder balls 14 and second solder balls 22 may be bonded to substrate 20 by applying heat such that first solder balls 14 melt sufficiently to bond to substrate 20 when the heat application is terminated. In certain embodiments, first solder balls 14 and second solder balls 22 may be similarly bonded to printed circuit board 16.

In practice, the steps of the method may be performed in any suitable order and may overlap in whole or in part according to certain integrated circuit fabrication, integrated circuit packaging, printed circuit board manufacturing, printed circuit board structure construction, or other considerations.

FIG. 5 illustrates an example printed circuit board structure 210 supporting one or more integrated circuit packages 212 using solder balls of multiple sizes, in which larger first solder balls 214 couple a substrate 216 to one or more first regions 218 of a printed circuit board 220 and smaller second solder balls 222 couple substrate 216 to one or more built-up regions 224 formed at one or more second regions 226 of printed circuit board 220. Although structure 210 may include any suitable number and types of integrated circuit packages 212, this description focuses for simplicity on a single integrated circuit package 212 with a substrate 216. Substrate 216 includes circuitry associated with its corresponding integrated circuit package 212 and surrounded by, for example, a dielectric or other suitable material. In certain embodiments, substrate 216 may include a standard laminate.

Structure 210 also includes printed circuit board 220 that includes circuitry surrounded by, for example, a dielectric or other suitable material. Printed circuit board 220 includes one or more first regions 218 each having a top surface 228 opposite a bottom surface 230 of substrate 216 and separated from bottom surface 230 of substrate 216 by a first distance 232. Printed circuit board 220 also includes one or more second regions 226 each having a top surface 234 opposite bottom surface 230 of substrate 216 and separated from bottom surface 230 of substrate 216 by a second distance 236. Top surface 234 of second region 226 is closer to bottom surface 230 of substrate 216 than top surface 228 of first region 218 such that second distance 236 is smaller than first distance 232. First distance 232 and second distance 236 may each be any suitable distance, and first region 218 and second region 226 may have any suitable areas, according to particular needs. Additionally, in an embodiment in which structure 210 includes multiple first regions 218, each first distance 232 may be any suitable distance and each first region 218 may have any suitable area relative to other first regions 218, according to particular needs. In an embodiment in which structure 210 includes multiple second regions 226, each second distance 236 may be any suitable distance and each second region 226 may have any suitable area relative to other second regions 226, according to particular needs.

Structure 210 includes one or more first solder balls 214 coupling substrate 216 to printed circuit board 220 at the one or more first regions 218 of printed circuit board 220 to provide electrical connectivity between circuitry associated with integrated circuit package 212 and circuitry associated with the printed circuit board 220. For example, first solder balls 214 may contact metal or other conductive material at both substrate 216 and printed circuit board 220 such that first solder balls 214 may provide electrical conductivity between circuitry associated with integrated circuit package 212 and printed circuit board 220. For example, first solder balls 214 may be used for power and ground connections. In certain embodiments, first solder balls 214 may include tin-lead, high lead, or may be lead free; however, the present invention contemplates first solder balls 214 including any suitable material according to particular needs. First solder balls 214 may have any suitable shape and material density. Although first solder balls 214 are illustrated as being the same size, first solder balls 214 may vary in size if appropriate. Additionally, although a specific number of first solder balls 214 are illustrated, structure 210 may include any suitable number of first solder balls 214 according to particular needs. First solder balls 214 may have any suitable pitch (i.e. center-to-center separation between first solder balls 214). Because of their larger size, first solder balls 214 may provide stronger physical connections to substrate 216 and printed circuit board 220 to provide better mechanical stability for printed circuit board structure 210, which may improve reliability.

Structure 210 also includes one or more second solder balls 222 coupling substrate 216 to printed circuit board 220 at the one or more second regions 226 of printed circuit board 220 to provide electrical connectivity between the circuitry associated with integrated circuit package 212 and the circuitry associated with printed circuit board 220. For example, second solder balls 222 may contact metal or other conductive material at both substrate 216 and printed circuit board 220 such that second solder balls 222 may provide electrical conductivity between circuitry associated with integrated circuit package 212 and printed circuit board 220. In certain embodiments, second solder balls 222 may include tin-lead, high lead, or may be lead free; however, the present invention contemplates second solder balls 222 including any suitable material according to particular needs. In one embodiment, second solder balls 222 include a different material than first solder balls 214. According to the present invention, second solder balls 222 are smaller than first solder balls 214, such that second distance 236 is smaller than first distance 232. Second solder balls 222 may have any suitable shape and material density. In one embodiment, it may be preferable for second solder balls 222 to be high density. Although second solder balls 222 are illustrated as being the same size, second solder balls 222 may vary in size if appropriate. Additionally, although a specific number of second solder balls 222 are illustrated, structure 210 may include any suitable number of second solder balls 222 according to particular needs. Second solder balls 222 may have any suitable pitch (i.e. center-to-center separation between second solder balls 222). For example, in certain embodiments, it may be possible to achieve pitches of less than 0.5 mm.

Although structure 210 is shown as including one row including first solder balls 214 and second solder balls 222, structure 210 may include first solder balls 214 and second solder balls 222 in any suitable arrangement within one or more first regions 218 and one or more second regions 226, respectively.

In one embodiment, each second region 226 of printed circuit board 220 includes a built-up region 224 (as illustrated in FIG. 5, for example) formed on top of a standard printed circuit board 220, second solder balls 222 coupling substrate 216 to printed circuit board 220 at each built-up region 224. Built-up region 224 may be formed in any suitable manner. In one embodiment, built-up region 224 may be an extension of printed circuit board 220. For example, printed circuit board 220 may be formed by depositing one or more laminate layers. These laminate layers may be pre-cut or stamped in such a way that built-up region 224 is formed as printed circuit board 220 is constructed. As another example, built-up region 224 may be formed using patterning and deposition techniques. As another example, built-up region 224 may include multiple metal layers. In one embodiment, built-up region 224 may include a dielectric material substantially the same as a dielectric material of printed circuit board 220; however, the present invention contemplates built-up region 224 including any suitable material. Built-up region 224 may have any suitable height, according to particular needs with respect to the sizes of first solder balls 214 and second solder balls 216. The height of built-up region 224 should ensure that, in a particular structure 210, first solder balls 214 make contact with both substrate 216 and printed circuit board 220, and second solder balls 222 make contact with both substrate 216 and built-up region 224.

In addition to certain features described above with reference to FIG. 5, FIG. 6 illustrates an example printed circuit board structure 210 supporting one or more integrated circuit packages 212 using solder balls of multiple sizes, in which larger first solder balls 214 couple substrate 216 to one or more recessed regions 238 formed at one or more first regions 218 of printed circuit board 220 and smaller second solder balls 222 couple substrate 216 to one or more second regions 226 of printed circuit board 220. In the printed circuit board structure 210 illustrated in FIG. 6, first regions 218 of printed circuit board 220 each include a recessed region 238, each first solder ball 214 coupling substrate 216 to printed circuit board 220 at the recessed region 238 of the first region 218 corresponding to the first solder ball 214.

Recessed regions 238 may have any suitable depths, according to particular needs. The depth of recessed regions 238 should ensure that, in a particular structure 210, first solder balls 214 make contact with both substrate 216 and printed circuit board 220, and second solder balls 222 make contact with both substrate 216 and printed circuit board 220. In one embodiment, top surface 228 of first region 218 may include the bottom of recessed regions 238 such that the first distance 232 of a first region 218 is the separation between the bottom of recessed region 238 and bottom surface 230 of substrate 216. Recessed regions 238 may include a metal contact or other suitable conductive material such that first solder balls 214 may provide electrical connectivity between circuitry associated with integrated circuit package 212 and printed circuit board 220.

Recessed regions 238 may be formed in any suitable manner, according to particular needs. For example, printed circuit board 220 may be formed by depositing one or more laminate layers. These laminate layers may be pre-cut or stamped in such a way that recessed regions 238 are formed as printed circuit board 220 is constructed. As another example, recessed regions 238 may be formed using any suitable patterning and etching techniques.

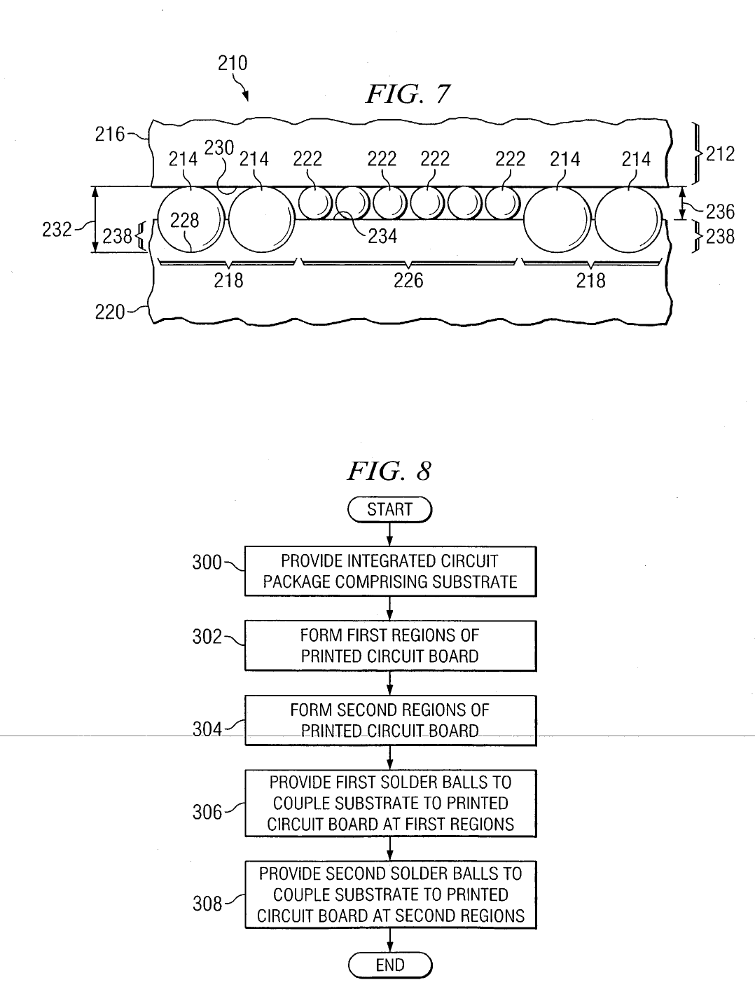

In addition to certain structures described above with reference to FIGS. 1 and 2, FIG. 7 illustrates an example printed circuit board structure 210 supporting one or more integrated circuit packages 212 using solder balls of multiple sizes, in which larger first solder balls 214 each couple substrate 216 to a corresponding recessed region 238 at a corresponding first region 218 of a printed circuit board 220 and smaller second solder balls 222 couple substrate 216 to one or more second regions 226 of printed circuit board 220. In the printed circuit board structure 210 illustrated in FIG. 7, each first solder ball 214 couples substrate 216 to printed circuit board 220 at a corresponding one of the recessed regions 238 and substantially fills the corresponding one of the recessed regions 238. For example, each first solder ball 214 may be embedded in its corresponding recessed region 238. In one embodiment, recessed regions 238 may each include a via extending into printed circuit board 220. In this embodiment, each first solder ball 214 substantially fills the via of its corresponding recessed region 238. Each recessed region 238 may form a substantially hemispherical-shaped and hole in printed circuit board 220. Each first region 218 may include any suitable number of recessed regions 238 in which a first solder ball 214 is embedded.

Recessed regions 238 may have any suitable depths, according to particular needs. The depth of recessed regions 238 should ensure that, in a particular structure 210, first solder balls 214 make contact with both substrate 216 and printed circuit board 220, and second solder balls 222 make contact with both substrate 216 and printed circuit board 220. In one embodiment, top surface 228 of first region 218 may include the bottom of recessed regions 238 such that the first distance 232 of a first region 218 is the separation of the bottom of recessed region 238 and bottom surface 230 of substrate 216. Recessed regions 238 may include a metal contact or other suitable conductive material such that first solder balls 214 may provide electrical connectivity between circuitry associated with integrated circuit package 212 and printed circuit board 220.

Recessed regions 238 may be formed in any suitable manner, according to particular needs. For example, printed circuit board 220 may be formed by depositing one or more laminate layers. These laminate layers may be pre-cut or stamped in such a way that recessed regions 238 are formed as printed circuit board 220 is constructed. As another example, recessed regions 238 may be formed using any suitable patterning and etching techniques such as an isotropic etching technique. As another example, recessed regions 238 may be formed using a drilling technique for drilling into printed circuit board 220. This may include, for example, drilling one or more laminate layers that make up some portion of printed circuit board 220 before using the laminate layers to form printed circuit board 220.

Particular embodiments of the present invention may provide one or more technical advantages. For example, in certain embodiments, solder balls of multiple sizes may be used to couple substrate 216 associated with integrated circuit package 212 to printed circuit board 220. The larger solder balls may provide stronger physical connections to substrate 216 and printed circuit board 220 to provide better mechanical stability for printed circuit board structure 210, which may improve reliability. These larger solder balls maybe used, for example, for power and ground connections. The smaller solder balls may provide a higher number of electrical connections between circuitry associated with integrated circuit package 212 and circuitry associated with printed circuit board 220, which may enable a high density interconnect between integrated circuit package 212 and printed circuit board 220. In certain embodiments, the solder ball pitch (i.e. center-to-center separation between certain solder balls) may be less than 0.5 mm.

FIG. 8 illustrates an example method for providing a printed circuit board structure 210 supporting one or more integrated circuit packages 212 using solder balls of multiple sizes. At step 300, at least one integrated circuit package 212 including substrate 216 is provided. Substrate 216 may include or may be coupled to circuitry associated with its corresponding integrated circuit package 212.

At steps 302 and 304, first regions 218 and second regions 226 of printed circuit board 220 are formed or otherwise provided. At step 302, one or more first regions 218 of printed circuit board 220 are formed or otherwise provided, each having top surface 228 opposite bottom surface 230 of substrate 216 and separated from bottom surface 230 of substrate 216 by a first distance 232. At step 304, one or more second regions 226 of printed circuit board 220 are provided, each having top surface 234 opposite bottom surface 230 of substrate 216 and separated from bottom surface 230 of substrate 216 by second distance 236, top surface 234 being closer to bottom surface 230 of substrate 16 than top surface 228 such that second distance 236 is smaller than first distance 232. Steps 302 and 304 may be performed at substantially the same time or in any order according to manufacturing considerations or other particular needs.

In the embodiment illustrated in FIG. 5, step 304 may include providing one or more built-up regions 224 at one or more second regions 226 of printed circuit board 220 on top of a standard printed circuit board 220. In an embodiment in which one or more built-up regions 224 are provided in each second region 226 of printed circuit board 220, each built-up region 224 may include a dielectric material substantially similar to a dielectric material of printed circuit board 220, although built-up region 224 may include any suitable material according to particular needs Built-up region 224 may be formed in any suitable manner. In one embodiment, built-up region 224 may be an extension of printed circuit board 220. For example, printed circuit board 220 may be formed by depositing one or more laminate layers. These laminate layers may be pre-cut or stamped in such a way that built-up region 224 is formed as printed circuit board 220 is constructed.

In the embodiment illustrated in FIG. 6, step 302 may include forming or otherwise providing one or more recessed regions 238 at one or more first regions 218 of printed circuit board 220 for receiving one or more first solder balls 214 to couple substrate 216 to the one or more recessed regions 238. A top surface 228 of first regions 218 may include the bottom of recessed regions 238, top surface 228 being separated from bottom surface 230 of substrate 216 by a first distance 232. Recessed regions 238 may be formed in any suitable manner, according to particular needs. For example, printed circuit board 220 may be formed by depositing one or more laminate layers. These laminate layers may be pre-cut or stamped in such a way that recessed regions 238 are formed as printed circuit board 220 is constructed. As another example, recessed regions 238 may be formed using any suitable patterning and etching techniques. In this embodiment, step 304 may include forming or otherwise providing one or more second regions 226 of printed circuit board 220, each having top surface 234 opposite bottom surface 230 of substrate 216 and separated from bottom surface 214 of substrate 216 by second distance 236, top surface 234 being elevated from top surface 228 such that second distance 236 is smaller than first distance 232.

In the embodiment illustrated in FIG. 7, step 302 may include forming or otherwise providing one or more recessed regions 238 at each of one or more first regions 218 of printed circuit board 220, each for receiving a first solder ball 214 to couple substrate 216 to a corresponding one of the recessed regions 238 at a corresponding one of the first regions 218 of printed circuit board 220 and to substantially fill the corresponding one of the recessed regions 238. A top surface 228 of first regions 218 may include the bottom of recessed regions 238, top surface 228 being separated from bottom surface 230 of substrate 216 by a first distance 232. In one embodiment, recessed regions 238 may each include a via extending into printed circuit board 220. Recessed regions 238 may be formed in any suitable manner, according to particular needs. For example, printed circuit board 220 may be formed by depositing one or more laminate layers. These laminate layers may be pre-cut or stamped in such a way that recessed regions 238 are formed as printed circuit board 220 is constructed. As another example, recessed regions 238 may be formed using any suitable patterning and etching techniques such as an isotropic etching technique. As another example, recessed regions 238 may be formed using a drilling technique for drilling into printed circuit board 220. This may include, for example, drilling one or more laminate layers that make up some portion of printed circuit board 220 before laying the laminate layers onto printed circuit board 220. In this embodiment, step 304 may include forming or otherwise providing one or more second regions 226 of printed circuit board 220, each having top surface 234 opposite bottom surface 230 of substrate 216 and separated from bottom surface 214 of substrate 216 by second distance 236, top surface 234 being elevated from top surface 228 such that second distance 236 is smaller than first distance 232.

At steps 306 and 308, which are preferably performed at substantially the same time, one or more first solder balls 214 and one or more second solder balls 222 are used to couple substrate 216 to printed circuit board 220. In one embodiment, as illustrated above with reference to FIG. 5, step 306 may include coupling one or more larger first solder balls 214 to substrate 216 and printed circuit board 220 at one or more first regions 218 of printed circuit board 220. In this embodiment, step 308 may include coupling one or more smaller second solder balls 222 to substrate 216 and one or more built-up regions 224 formed at the one or more second regions 226 of printed circuit board 220. In another embodiment, as illustrated with reference to FIG. 6, step 306 may include coupling one or more larger first solder balls 214 to substrate 216 and one or more recessed regions 238 formed at one or more first regions 218 of printed circuit board 220. In this embodiment, step 308 may include coupling one or more smaller second solder balls 222 to substrate 216 and to one or more second regions 226 of printed circuit board 226. In yet another embodiment, as illustrated with reference to FIG. 7, step 306 may include coupling each of one or more larger first solder balls 214 to substrate 216 and a corresponding recessed region 238 at a corresponding first region 218 of printed circuit board 220, each first solder ball 214 substantially filling its corresponding recessed region 238. In this embodiment, step 308 may include coupling one or more smaller second solder balls 222 to substrate 216 and one or more second regions 226 of printed circuit board 220.

The one or more first solder balls 214 and the one or more second solder balls 222 may provide electrical connectivity between circuitry associated with integrated circuit package 212 and circuitry associated with printed circuit board 220. In one embodiment, first solder balls 214 and second solder balls 222 may be bonded to printed circuit board 220 by applying heat such that first solder balls 214 melt sufficiently to bond to printed circuit board 220 when the heat application is terminated. In certain embodiments, first solder balls 214 and second solder balls 222 may be similarly bonded to substrate 216.

In practice, the steps of the method may be performed in any suitable order and may overlap in whole or in part according to certain integrated circuit fabrication, integrated circuit packaging, printed circuit board manufacturing, printed circuit board structure construction, or other considerations.

Although the present invention has been described with several embodiments, diverse changes, substitutions, variations, alterations, and modifications may be suggested to one skilled in the art, and it is intended that the invention encompass all such changes, substitutions, variations, alterations, and modifications as fall within the spirit and scope of the appended claims.

What is claimed is:

1. An electrical device structure supporting one or more semiconductor structures, comprising:
at least one electrical device having a first surface;
at least one semiconductor structure, comprising:
one or more first regions each having a second surface opposite the first surface of the electrical device and separated from the first surface of the electrical device by a first distance; and
one or more second regions each having a second surface opposite the first surface of the electrical device and separated from the first surface of the electrical device by a second distance, the second surface of the second region being closer to the first surface of the electrical device than the second surface of the first region such that the second distance is smaller than the first distance;
one or more first solder balls coupling the electrical device to the semiconductor structure at the one or more first regions of the semiconductor structure to provide electrical connectivity between circuitry associated with the semiconductor structure and circuitry associated with the electrical device; and
one or more second solder balls coupling the semiconductor structure to the electrical device at the one or more second regions of the semiconductor structure to provide electrical connectivity between the circuitry associated with the electrical device and the circuitry associated with the semiconductor structure, the one or more second solder balls being smaller than the one or more first solder balls.

2. The structure of claim 1, wherein the semiconductor structure comprises at least one of:
a semiconductor device;
an integrated circuit; and
an integrated circuit package.

3. The structure of claim 1, wherein the electrical device comprises at least one of:
a semiconductor device;
an integrated circuit;
an integrated circuit package;
a printed circuit board;
an electrical component; and
an electronics device.

4. The structure of claim 1, wherein the first surface comprises a top surface of the at least one electrical device and the second surface comprises a bottom surface of the at least one semiconductor structure.

5. The structure of claim 1, wherein the first surface comprises a bottom surface of the at least one electrical device and the second surface comprises a top surface of the at least one semiconductor structure.

6. The structure of claim 1, wherein the one or more first regions of the semiconductor structure each comprise a recessed region, each first solder ball of a corresponding one of the first regions coupling the electrical device to the semiconductor structure at the recessed region.

7. The structure of claim 1, wherein the one or more first regions of the semiconductor structure each comprise one or more recessed regions, each first solder ball coupling the electrical device to the semiconductor structure at a corresponding one of the recessed regions and substantially filling the corresponding one of the recessed regions.

8. The structure of claim 7, wherein each recessed region comprises a via extending into the semiconductor structure.

9. The structure of claim 7, wherein the one or more recessed regions have been formed using a drilling technique for drilling into the semiconductor structure.

10. The structure of claim 1, wherein each second region of the semiconductor structure comprises a built-up region formed on the bottom of a standard semiconductor structure.

11. The structure of claim 10, wherein each built-up region comprises a dielectric material substantially the same as a dielectric material of the semiconductor structure.

12. A printed circuit board structure supporting one or more integrated circuit packages, comprising:
at least one printed circuit board having a top surface;
at least one integrated circuit package comprising a substrate, the substrate comprising:
one or more first regions each having a bottom surface opposite the top surface of the printed circuit board and separated from the top surface of the printed circuit board by a first distance; and
one or more second regions each having a bottom surface opposite the top surface of the printed circuit board and separated from the top surface of the printed circuit board by a second distance, the bottom surface of the second region being closer to the top surface of the printed circuit board than the bottom surface of the first region such that the second distance is smaller than the first distance;
one or more first solder balls coupling the printed circuit board to the substrate at the one or more first regions of the substrate to provide electrical connectivity between circuitry associated with the printed circuit board and circuitry associated with the integrated circuit package; and
one or more second solder balls coupling the printed circuit board to the substrate at the one or more second regions of the substrate to provide electrical connectivity between the circuitry associated with the printed circuit board and the circuitry associated with the integrated circuit package, the one or more second solder balls being smaller than the one or more first solder balls.

13. The structure of claim 12, wherein the one or more first regions of the substrate each comprise a recessed region, each first solder ball of a corresponding one of the first regions coupling the printed circuit board to the substrate at the recessed region.

14. The structure of claim 12, wherein the one or more first regions of the substrate each comprise one or more recessed regions, each first solder ball coupling the printed circuit board to the substrate at a corresponding one of the recessed regions and substantially filling the corresponding one of the recessed regions.

15. The structure of claim 14, wherein each recessed region comprises a via extending into the substrate.

16. The structure of claim 14, wherein the one or more recessed regions have been formed using a drilling technique for drilling into the substrate.

17. The structure of claim 14, wherein the one or more recessed regions have been formed using standard patterning and etching techniques to form substantially hemispherical-shaped holes in the substrate, each hole corresponding to a recessed region.

18. The structure of claim 12, wherein each second region of the substrate comprises a built-up region formed on the bottom of a standard substrate.

19. The structure of claim 18, wherein each built-up region comprises a dielectric material substantially the same as a dielectric material of the substrate.

20. The structure of claim 18, wherein each built-up region comprises multiple metal layers.

21. A method for providing a printed circuit board structure supporting one or more integrated circuit packages, comprising:
providing at least one printed circuit board having a top surface;
providing at least one integrated circuit package comprising a substrate, the substrate comprising:
one or more first regions of the substrate each having a bottom surface opposite the top surface of the printed circuit board and separated from the top surface of the printed circuit board by a first distance; and
one or more second regions of the substrate each having a bottom surface opposite the top surface of the printed circuit board and separated from the top surface of the printed circuit board by a second distance, the bottom surface of the second region being closer to the top surface of the printed circuit board than the bottom surface of the first region such that the second distance is smaller than the first distance;
using one or more first solder balls to couple the printed circuit board to the substrate at the one or more first regions of the substrate to provide electrical connectivity between circuitry associated with the printed circuit board and circuitry associated with the integrated circuit package; and
using one or more second solder balls to couple the printed circuit board to the substrate at the one or more second regions of the substrate to provide electrical connectivity between the circuitry associated with the printed circuit board and the circuitry associated with the integrated circuit package, the one or more second solder balls being smaller in size than the one or more first solder balls.

22. The method of claim 21, wherein the one or more first regions of the substrate each comprise a recessed region, each first solder ball of a corresponding one of the first regions coupling the printed circuit board to the substrate at the recessed region.

23. The method of claim 21, wherein the one or more first regions of the substrate each comprise one or more recessed regions, each first solder ball coupling the printed circuit board to the substrate at a corresponding one of the recessed regions and substantially filling the corresponding one of the recessed regions.

24. The method of claim 23, wherein each recessed region comprises a via extending into the substrate.

25. The method of claim 23, comprising forming the one or more recessed regions using a drilling technique for drilling into the substrate.

26. The method of claim 23, comprising forming the one or more recessed regions using standard patterning and etching techniques to form substantially hemispherical-shaped holes in the substrate, each hole corresponding to a recessed region.

27. The method of claim 21, wherein each second region of the substrate comprises a built-up region formed on the bottom of a standard substrate.

28. The method of claim 27, wherein each built-up region comprises a dielectric material substantially the same as a dielectric material of the substrate.

29. The method of claim 27, wherein each built-up region comprises multiple metal layers.

30. An integrated circuit package for coupling to one or more printed circuit boards, comprising:
one or more first regions of a substrate of the integrated circuit package, each first region having a bottom surface adapted to receive one or more first solder balls for coupling the bottom surface of the first region to an opposing top surface of a printed circuit board such that the bottom surface of the first region and the top surface of the printed circuit board are separated by a first distance; and
one or more second regions of the substrate each having a bottom surface adapted to receive one or more second solder balls for coupling the bottom surface of the second region to an opposing top surface of the printed circuit board such that the bottom surface of the second region and the top surface of the printed circuit board are separated by a second distance that is smaller than the first distance, the one or more second solder balls being smaller than the one or more first solder balls.

31. The package of claim 30, wherein the one or more first regions of the substrate each comprise a recessed region for receiving the one or more first solder balls corresponding to the first region.

32. The package of claim 30, wherein the one or more first regions of the substrate each comprise one or more recessed regions each for receiving a first solder ball to couple the printed circuit board to a corresponding one of the recessed regions and to substantially fill the corresponding one of the recessed regions.

33. The package of claim 32, wherein each recessed region comprises a via extending into the substrate.

34. The package of claim 32, wherein the one or more recessed regions have been formed using a drilling technique for drilling into the substrate.

35. The package of claim 32, wherein the one or more recessed regions have been formed using standard patterning and etching techniques to form substantially hemispherical-shaped holes in the substrate, each hole corresponding to a recessed region.

36. The package of claim 30, wherein each second region of the substrate comprises a built-up region formed on the bottom of a standard substrate.

37. The package of claim 36, wherein each built-up region comprises a dielectric material substantially the same as a dielectric material of the substrate.

38. The package of claim 36, wherein each built-up region comprises multiple metal layers.

39. A method for providing an integrated circuit package for coupling to one or more printed circuit boards, comprising:
providing one or more first regions of a substrate of the integrated circuit package, each first region having a bottom surface adapted to receive one or more first solder balls for coupling the bottom surface of the first region to an opposing top surface of at least one printed circuit board such that the bottom surface of the first region and the top surface of the printed circuit board are separated by a first distance; and
providing one or more second regions of the substrate each having a bottom surface adapted to receive one or more second solder balls for coupling the bottom surface of the second region to an opposing top surface of the printed circuit board such that the bottom surface of the second region and the top surface of the printed circuit board are separated by a second distance that is smaller than the first distance, the one or more second solder balls being smaller in size than the one or more first solder balls.

40. The method of claim 39, wherein the one or more first regions of the substrate each comprise a recessed region for receiving the one or more first solder balls corresponding to the first region.

41. The method of claim 39, wherein the one or more first regions of the substrate each comprise one or more recessed regions each for receiving a first solder ball to couple the printed circuit board to a corresponding one of the recessed regions and to substantially fill the corresponding one of the recessed regions.

42. The method of claim 41, wherein each recessed region comprises a via extending into the substrate.

43. The method of claim 41, comprising forming the one or more recessed regions using a drilling technique for drilling into the substrate.

44. The method of claim 41, comprising forming the one or more recessed regions using standard patterning and etching techniques to form substantially hemispherical-shaped holes in the substrate, each hole corresponding to a recessed region.

45. The method of claim 39, wherein each second region of the substrate comprises a built-up region formed on the bottom of a standard substrate.

46. The method of claim 45, wherein each built-up region comprises a dielectric material substantially the same as a dielectric material of the substrate.

47. The method of claim 45, wherein each built-up region comprises multiple metal layers.

48. A printed circuit board structure supporting one or more integrated circuit packages, comprising:
at least one integrated circuit package comprising a substrate having a bottom surface;
a printed circuit board comprising:
one or more first regions each having a top surface opposite the bottom surface of the substrate and separated from the bottom surface of the substrate by a first distance; and
one or more second regions each having a top surface opposite the bottom surface of the substrate and separated from the bottom surface of the substrate by a second distance, the top surface of the second region being closer to the bottom surface of the integrated circuit package than the top surface of the first region such that the second distance is smaller than the first distance;
one or more first solder balls coupling the substrate to the printed circuit board at the one or more first regions of the printed circuit board to provide electrical connectivity between circuitry associated with the integrated circuit package and circuitry associated with the printed circuit board; and
one or more second solder balls coupling the substrate to the printed circuit board at the one or more second regions of the printed circuit board to provide electrical connectivity between the circuitry associated with the integrated circuit package and the circuitry associated with the printed circuit board, the one or more second solder balls being smaller than the one or more first solder balls.

49. The structure of claim 48, wherein the one or more first regions of the printed circuit board each comprise a recessed region, each first solder ball of a corresponding one of the first regions coupling the substrate to the printed circuit board at the recessed region.

50. The structure of claim 48, wherein the one or more first regions of the printed circuit board each comprise one or more recessed regions, each first solder ball coupling the substrate to the printed circuit board at a corresponding one of the recessed regions and substantially filling the corresponding one of the recessed regions.

51. The structure of claim 50, wherein each recessed region comprises a via extending into the printed circuit board.

52. The structure of claim 50, wherein the one or more recessed regions have been formed using a drilling technique for drilling into the printed circuit board.

53. The structure of claim 50, wherein the one or more recessed regions have been formed using standard patterning and etching techniques to form substantially hemispherical-shaped holes in the printed circuit board, each hole corresponding to a recessed region.

54. The structure of claim 48, wherein each second region of the printed circuit board comprises a built-up region formed on top of a standard printed circuit board.

55. The structure of claim 54, wherein each built-up region comprises a dielectric material substantially the same as a dielectric material of the printed circuit board.

56. The structure of claim 54, wherein each built-up region comprises multiple metal layers.

57. A method for providing a printed circuit board structure supporting one or more integrated circuit packages, comprising:
providing at least one integrated circuit package comprising a substrate having a bottom surface;
providing a printed circuit board comprising:
one or more first regions of the printed circuit board each having a top surface opposite the bottom surface of the substrate and separated from the bottom surface of the substrate by a first distance; and
one or more second regions of the printed circuit board each having a top surface opposite the bottom surface of the substrate and separated from the bottom surface of the substrate by a second distance, the top surface of the second region being closer to the bottom surface of the integrated circuit package than the top surface of the first region such that the second distance is smaller than the first distance;
using one or more first solder balls to couple the substrate to the printed circuit board at the one or more first regions of the printed circuit board to provide electrical connectivity between circuitry associated with the integrated circuit package and circuitry associated with the printed circuit board; and
using one or more second solder balls to couple the substrate to the printed circuit board at the one or more second regions of the printed circuit board to provide electrical connectivity between the circuitry associated with the integrated circuit package and the circuitry associated with the printed circuit board, the one or more second solder balls being smaller in size than the one or more first solder balls.

58. The method of claim 57, wherein the one or more first regions of the printed circuit board each comprise a recessed region, each first solder ball of a corresponding one of the first regions coupling the substrate to the printed circuit board at the recessed region.

59. The method of claim 57, wherein the one or more first regions of the printed circuit board each comprise one or more recessed regions, each first solder ball coupling the substrate to the printed circuit board at a corresponding one of the recessed regions and substantially filling the corresponding one of the recessed regions.

60. The method of claim 59, wherein each recessed region comprises a via extending into the printed circuit board.

61. The method of claim 59, comprising forming the one or more recessed regions using a drilling technique for drilling into the printed circuit board.

62. The method of claim 59, comprising forming the one or more recessed regions using standard patterning and etching techniques to form substantially hemispherical-shaped holes in the printed circuit board, each hole corresponding to a recessed region.

63. The method of claim 57, wherein each second region of the printed circuit board comprises a built-up region formed on top of a standard printed circuit board.

64. The method of claim 63, wherein each built-up region comprises a dielectric material substantially the same as a dielectric material of the printed circuit board.

65. The method of claim 63, wherein each built-up region comprises multiple metal layers.

66. A printed circuit board for supporting one or more integrated circuit packages, comprising:
one or more first regions each having a top surface adapted to receive one or more first solder balls for coupling the top surface of the first region to an opposing bottom surface of a substrate of at least one integrated circuit package such that the top surface of the first region and the bottom surface of the substrate are separated by a first distance; and
one or more second regions each having a top surface adapted to receive one or more second solder balls for coupling the top surface of the second region to an opposing bottom surface of the substrate such that the top surface of the second region and the bottom surface of the substrate are separated by a second distance that is smaller than the first distance, the one or more second solder balls being smaller than the one or more first solder balls.

67. The printed circuit board of claim 66, wherein the one or more first regions of the printed circuit board each comprise a recessed region for receiving the one or more first solder balls corresponding to the first region.

68. The printed circuit board of claim 66, wherein the one or more first regions of the printed circuit board each comprise one or more recessed regions each for receiving a first solder ball to couple the substrate to a corresponding one of the recessed regions and to substantially fill the corresponding one of the recessed regions.

69. The printed circuit board of claim 68, wherein each recessed region comprises a via extending into the printed circuit board.

70. The printed circuit board of claim 68, wherein the one or more recessed regions have been formed using a drilling technique for drilling into the printed circuit board.

71. The printed circuit board of claim 68, wherein the one or more recessed regions have been formed using standard patterning and etching techniques to form substantially hemispherical-shaped holes in the printed circuit board, each hole corresponding to a recessed region.

72. The printed circuit board of claim 66, wherein each second region of the printed circuit board comprises a built-up region formed on top of a standard printed circuit board.

73. The printed circuit board of claim 72, wherein each built-up region comprises a dielectric material substantially the same as a dielectric material of the printed circuit board.

74. The printed circuit board of claim 72, wherein each built-up region comprises multiple metal layers.

75. A method for providing a printed circuit board for supporting one or more integrated circuit packages, comprising:
providing one or more first regions each having a top surface adapted to receive one or more first solder balls for coupling the top surface of the first region to an opposing bottom surface of a substrate of at least one integrated circuit package such that the top surface of the first region and the bottom surface of the substrate are separated by a first distance; and
providing one or more second regions each having a top surface adapted to receive one or more second solder balls for coupling the top surface of the second region to an opposing bottom surface of the substrate such that the top surface of the second region and the bottom surface of the substrate are separated by a second distance that is smaller than the first distance, the one or more second solder balls being smaller in size than the one or more first solder balls.

76. The method of claim 75, wherein the one or more first regions of the printed circuit board each comprise a recessed region for receiving the one or more first solder balls corresponding to the first region.

77. The method of claim 75, wherein the one or more first regions of the printed circuit board each comprise one or more recessed regions each for receiving a first solder ball to couple the substrate to a corresponding one of the recessed regions and to substantially fill the corresponding one of the recessed regions.

78. The method of claim 77, wherein each recessed region comprises a via extending into the printed circuit board.

79. The method of claim 77, comprising forming the one or more recessed regions using a drilling technique for drilling into the printed circuit board.

80. The method of claim 77, comprising forming the one or more recessed regions using standard patterning and etching techniques to form substantially hemispherical-shaped holes in the printed circuit board, each hole corresponding to a recessed region.

81. The method of claim 75, wherein each second region of the printed circuit board comprises a built-up region formed on top of a standard printed circuit board.

82. The method of claim 81, wherein each built-up region comprises a dielectric material substantially the same as a dielectric material of the printed circuit board.

83. The method of claim 81, wherein each built-up region comprises multiple metal layers.
